(19) United States
(12) Patent Application Publication
(10) Pub. No.: US 2026/0312152 A1
(43) Pub. Date: Oct. 8, 2026

(54) WIRELESS COMMUNICATION SYSTEM AND WIRELESS COMMUNICATION METHOD

(71) Applicant: Astemo, Ltd., Tokyo (JP)

(72) Inventors: Takanori YAMAZOE, Tokyo (JP); Daiki KOMATSU, Tokyo (JP); Mutsumi KIKUCHI, Ibaraki (JP); Jun SUZUKI, Ibaraki (JP); Ei O, Ibaraki (JP)

(21) Appl. No.: 19/483,163

(22) PCT Filed: Mar. 19, 2024
(86) PCT No.: PCT/JP2024/010662

§ 371 Date: Nov. 10, 2025

(30) Foreign Application Priority Data
May 11, 2023 (JP) 2023-078389

(51) Int. Cl. H01M 10/42; G01R 31/371; G01R 31/374; G01R 31/3842; G01R 31/396; H02J 7/52

(52) U.S. Cl. CPC H01M 10/425; G01R 31/371; G01R 31/374; G01R 31/3842; G01R 31/396; H01M 2010/4271; H01M 2010/4278; H02J 7/52

(57) ABSTRACT

Provided is a wireless communication system or the like which appropriately detects a change in an arrangement state of parts in a battery pack. A wireless communication system detects, on the basis of a change in reception strength when wireless communication is performed between a master and slaves each including an antenna or the like, a change in an arrangement state of parts, including the master and the slaves, arranged inside a battery pack. The components each including an antenna or the like include a plurality of which are connected one-to-one to a plurality of battery modules inside the battery pack, and a master which performs wireless communication with the plurality of slaves.

### TECHNICAL FIELD

The present disclosure relates to a wireless communication system and the like.

### BACKGROUND ART

As a technique for detecting a drop of a battery module in a battery pack, for example, a technique described in PTL 1 is known. That is, PTL 1 describes a voltage detection device including “a wireless communication unit which performs wireless communication with an external device, and a determination unit which determines a drop of the battery module from a change in a communication state of the wireless communication unit”.

### CITATION LIST

### Patent Literature

PTL 1: JP 2022-83636 A.

### SUMMARY OF INVENTION

### Technical Problem

In the technique described in PTL 1, a predetermined external device (inspection equipment) is used when a drop of the battery module is detected. In such a configuration, it is difficult to detect the drop of the battery module other than at a time of inspecting the battery module, and thus there is room for improvement.

In this regard, an object of the present disclosure is to provide a wireless communication system or the like which appropriately detects a change in an arrangement state of parts in a battery pack.

### Solution to Problem

In order to solve the above problem, a wireless communication system according to the present disclosure detects, on the basis of a change in reception strength when wireless communication is performed between a plurality of components each including a wireless communication unit, a change in an arrangement state of parts, including the plurality of components, arranged inside a battery pack.

### Advantageous Effects of Invention

According to the present disclosure, it is possible to provide the wireless communication system or the like which appropriately detects a change in an arrangement state of parts in a battery pack.

### BRIEF DESCRIPTION OF DRAWINGS

FIG. 1 is a configuration diagram including a wireless communication system according to a first embodiment.

FIG. 2 is an explanatory diagram illustrating a relationship between a master and a plurality of slaves in the wireless communication system according to the first embodiment.

FIG. 3 is a communication timing diagram illustrating processing of the master and the plurality of slaves in the wireless communication system according to the first embodiment.

FIG. 4 is a sequence diagram in a case where communication is normally performed in the wireless communication system according to the first embodiment.

FIG. 5 is a configuration diagram including the wireless communication system according to the first embodiment, and illustrates a state where a position of the slave changes inside the battery pack.

FIG. 6 is a sequence diagram in a case where the position of the slave changes in the wireless communication system according to the first embodiment.

FIG. 7 is a flowchart related to processing of the slave of the wireless communication system according to the first embodiment.

FIG. 8A is a flowchart related to processing of the master of the wireless communication system according to the first embodiment.

FIG. 8B is a flowchart related to processing of the master of the wireless communication system according to the first embodiment.

FIG. 9 is an explanatory diagram illustrating a relationship between a master and a plurality of slaves in a wireless communication system according to a modification of the first embodiment.

FIG. 10 is a flowchart related to processing of a master of a wireless communication system according to a second embodiment.

FIG. 11 is a flowchart related to processing of a master of a wireless communication system according to a third embodiment.

FIG. 12 is an explanatory diagram illustrating an example of a frequency characteristic of a reception strength between a master and a slave in a wireless communication system according to a fourth embodiment.

FIG. 13 is an explanatory diagram illustrating an example of the frequency characteristic of the reception strength between the master and the slave in the wireless communication system according to the fourth embodiment, and illustrates a case where a null point disappears as the position of the slave changes.

### DESCRIPTION OF EMBODIMENTS

### First Embodiment

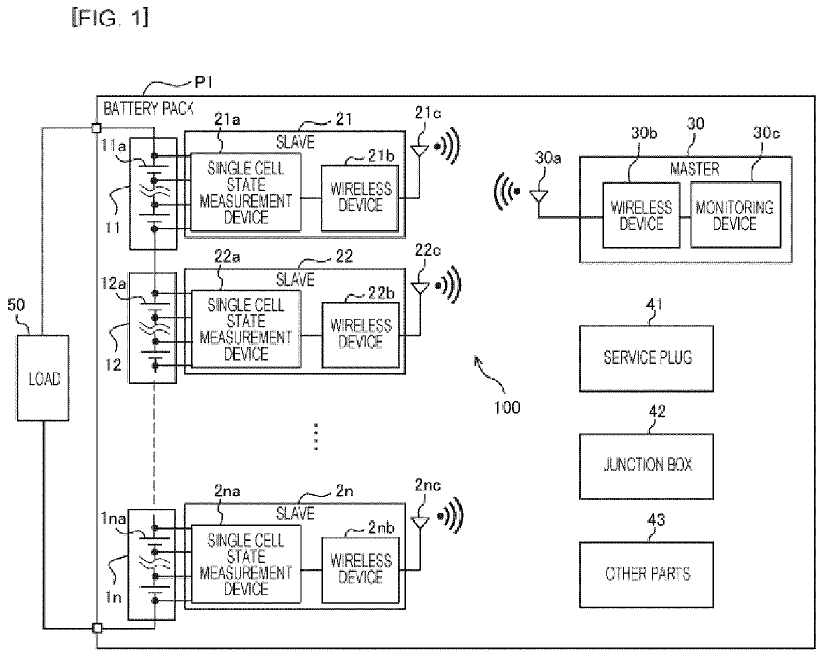

Hereinafter, a battery pack P1 (see FIG. 1) including battery modules 11, 12,. In (see FIG. 1) will be briefly described, and then a wireless communication system 100 (see FIG. 1) will be described in detail.

### <Configuration of Battery Pack>

FIG. 1 is a configuration diagram including the wireless communication system 100 according to a first embodiment.

The battery pack P1 illustrated in FIG. 1 is a metal housing which houses the battery modules 11, 12, . . . , 1n, as well as slaves 21, 22, . . . , 2n (components, battery data transmission devices) and a master 30 (component, battery management device). In the example of FIG. 1, in addition to the above-described configurations, a service plug 41 (part), a junction box 42 (part), and other parts 43 (parts) are also housed in the battery pack P1.

Note that the battery pack P1 can be made of resin, but transmits radio waves in the case of resin, and reflects radio waves in the case of metal. In addition, in a case where the battery pack P1 is made of a reinforced resin using carbon fibers, carbon fibers may be used as a radio wave absorbing material, and radio waves are absorbed. In the present embodiment, the battery pack P1 is made of metal which reflects radio waves as described above.

The battery pack P1 is mounted on, for example, a battery electric vehicle (BEV) or a hybrid electric vehicle (HEV). Note that the battery pack P1 may be mounted on a moving body such as a railway vehicle, an aircraft, a drone, or a ship. In addition, the battery pack P1 may be used as a power storage facility such as a backup power supply of a data center.

The battery module 11 has a configuration in which a plurality of single battery cells 11a (also referred to as single cells) are connected in series or in series and parallel. In the example of FIG. 1, the plurality of single battery cells 11a are connected in series to constitute a battery module 11. The single battery cell 11a is a secondary battery capable of charging and discharging. As such a single battery cell 11a, for example, a lithium ion battery is used, but the single battery cell 11a is not limited thereto.

Each of the other battery modules 12, . . . , 1n illustrated in FIG. 1 has a configuration similar to that of the battery module 11. Then, the plurality of battery modules 11, 12, In are housed in the battery pack P1 in a state of being connected in series (or in series and parallel). As illustrated in FIG. 1, a series connection body of the battery modules 11, 12, In is electrically connected to a load 50. The load 50 is a device driven by power supplied from the battery modules 11, 12, . . . , 1n, and is provided outside the battery pack P1. Note that a converter (not illustrated) or an inverter (not illustrated) that performs predetermined power conversion may be included in the load 50.

The service plug 41 illustrated in FIG. 1 switches connection or disconnection of a predetermined power supply circuit, and is electrically connected to the battery modules 11, 12, . . . , 1n. The junction box 42 is a box for connecting power lines or the like, and is electrically connected to the battery modules 11, 12, . . . , 1n. The other parts 43 are, for example, power line cables or connectors, and are electrically connected to the battery modules 11, 12, . . . , 1n.

### <Configuration of Wireless Communication System>

The wireless communication system 100 illustrated in FIG. 1 is a system which wirelessly transmits data such as voltages and temperatures of the battery modules 11, 12, . . . , 1n from the slaves 21, 22, 2n to the master 30. The wireless communication system 100 also has a function of detecting movement of the slaves 21, 22, . . . , 2n and the master 30 in the battery pack P1 on the basis of a change in reception strength when wireless communication is performed between the slaves 21, 22, . . . , 2n and the master 30. Such a wireless communication system 100 includes n slaves 21, 22, . . . , 2n and one master 30.

The slave 21 measures a state variable such as a voltage or a temperature of the battery module 11 in response to a command from the master 30, and transmits the measured value to the master 30. Similarly, the other slaves 22, . . . , 2n transmit the measured values such as the voltages of the battery modules 12, . . . , 2n to the master 30. The plurality of slaves 21, 22, . . . , 2n (battery data transmission devices) are connected so as to correspond one-to-one with the plurality of battery modules 11, 12, . . . , 1n inside the battery pack P1.

As illustrated in FIG. 1, the slave 21 connected to the battery module 11 includes a single cell state measurement device 21a, a wireless device 21b (wireless communication unit), and an antenna 21c (wireless communication unit). The single cell state measurement device 21a is a device which measures a predetermined state variable for each of the plurality of single battery cells 11a. Examples of such a state variable include a voltage, a temperature, and a current of the single battery cell 11a.

The wireless device 21b is a device used for wireless communication, and is connected to the single cell state measurement device 21a via a wiring and is connected to the antenna 21c via another wiring. The wireless device 21b extracts a predetermined signal (for example, a Request command, an ACK, or an NAK from the master 30) from the radio wave received by the antenna 21c, and reads a measured value such as a voltage from the single cell state measurement device 21a according to the signal. Then, the wireless device 21b converts a measured value such as a voltage into a predetermined signal, and outputs the signal to the antenna 21c. The antenna 21c transmits and receives radio waves. As described above, the slave 21 which is one of the “components” of the battery pack P1 includes the wireless device 21b and the antenna 21c as the “wireless communication unit”.

Note that a cell controller (not illustrated) which adjusts charging and discharging so as to equalize charge levels of the plurality of single battery cells 11a may be provided in the slave 21. Since the other slaves 22, . . . , 2n each have a configuration similar to that of the slave 21, the description thereof is omitted.

The master 30 is a device which monitors the states of the battery modules 11, 12, . . . , 1n and controls charging and discharging on the basis of radio signals received from the slaves 21, 22, . . . , 2n. For example, the master 30 controls charging and discharging so as to suppress overcharge or overdischarge, on the basis of states of charge (SOC) and deterioration levels of the battery modules 11, 12, . . . , 1n. The master 30 (battery management device) performs wireless communication with the plurality of slaves 21, 22, . . . , 2n (battery data transmission devices) inside the battery pack P1.

As illustrated in FIG. 1, the master 30 includes an antenna 30a (wireless communication unit), a wireless device 30b (wireless communication unit), and a monitoring device 30c. The antenna 30a transmits and receives radio waves, and is connected to the wireless device 30b via a wiring. The wireless device 30b is a device which performs predetermined processing according to signals from the antenna 30a and the monitoring device 30c. That is, the wireless device 30b extracts a predetermined signal (for example, the voltage data received from the slave 21) from the radio wave received by antenna 30a, and outputs the signal to the monitoring device 30c. In addition, the wireless device 30b converts a signal (for example, a Request command, an ACK, or an NAK) from the monitoring device 30c into a predetermined signal and outputs the signal to the antenna 30a. As described above, the master 30 which is one of the “components” of the battery pack P1 includes the antenna 30a and the wireless device 30b as the “wireless communication unit”.

The monitoring device 30c is, for example, a microcomputer, and although not illustrated, includes a central processing unit (CPU), a read only memory (ROM), a random access memory (RAM), and various interfaces. Then, the program stored in the ROM is read and developed in the RAM, and the CPU executes various types of processing. The monitoring device 30c monitors the states of the battery modules 11, 12, . . . , 1n and generates a predetermined signal for controlling charging and discharging as necessary. In addition, the monitoring device 30c also has a function of determining whether or not the master 30, the slaves 21, 22, . . . , 2n, or the like have moved, on the basis of a change in reception strength when wireless communication is performed with the slaves 21, 22, . . . , 2n.

That is, the wireless communication system 100 detects a change in the arrangement state of parts, including the master 30 or the slaves 21, 22, . . . , 2n (a plurality of components), arranged inside the battery pack P1, on the basis of a change in reception strength when wireless communication is performed between the master 30 and the slaves 21, 22, . . . , 2n (between a plurality of components). Although details will be described later, the above-described “part” also includes peripheral parts, which do not perform wireless communication, such as the service plug 41, the junction box 42, and the other parts 43.

Although not illustrated, the monitoring device 30c is connected to a host central processing unit (CPU) via a wiring. In the case of detecting a predetermined abnormality (a change in arrangement state) such as movement of the master 30, the slaves 21, 22, . . . , 2n, or the like inside the battery pack P1, the monitoring device 30c notifies a host CPU (not illustrated) of the detection result.

In this manner, master-slave wireless communication is performed between the master 30 and the slaves 21, 22, . . . , 2n, so that wireless operation can be achieved. As a result, weight reduction, cost reduction, and compactness of the battery pack P1 can be achieved, and a degree of freedom in layout when the battery pack P1 is mounted on a moving body (not illustrated) can be increased. In addition, by wireless communication, it is possible to easily perform an operation of extracting out and replacing only a battery module including a deteriorated single battery cell.

The master 30 and the slaves 21, 22, . . . , 2n are fixed to the metal battery pack P1 with screws or the like. Further, the peripheral parts such as the service plug 41, the junction box 42, and the other parts 43 are also fixed to the battery pack P1. Since the parts are fixed inside the battery pack P1 in this manner, a relative positional relationship (that is, an arrangement state) of the parts including the slaves 21, 22, . . . , 2n and the master 30 hardly changes unless a large impact or vibration acts. Further, the battery pack P1 is made of metal, and is less likely to receive interference of radio waves from the outside. Therefore, normally, the reception strength hardly changes when the master 30 and the slaves 21, 22, . . . , 2n receive radio signals.

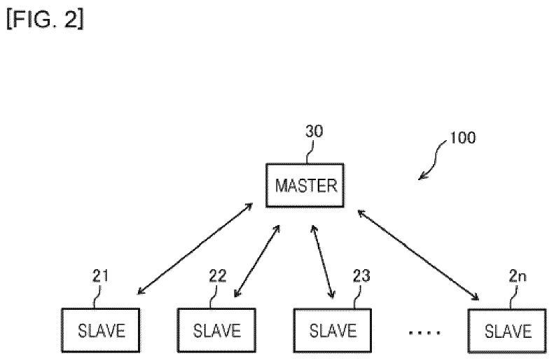

FIG. 2 is an explanatory diagram illustrating a relationship between the master 30 and the plurality of slaves 21, 22, . . . , 2n.

As illustrated in FIG. 2, the master 30 corresponds to the slaves 21, 22, . . . , 2n in a one-to-n relationship. Then, as described below, a radio signal such as voltage data is transmitted from the slaves 21, 22, . . . , 2n to the master 30 in response to the Request command from the master 30.

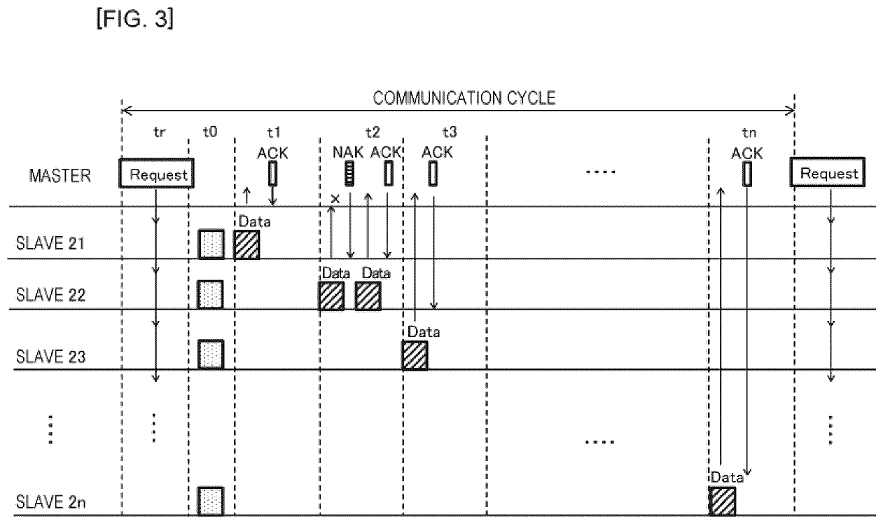

FIG. 3 is a communication timing diagram illustrating processing of the master 30 and the plurality of slaves 21, 22, . . . , 2n.

Note that a horizontal axis in FIG. 3 represents a time. In addition, a vertical axis in FIG. 3 indicates the processing of the master 30 and the processing of the slaves 21, 22, 23, . . . , 2n in order from the top of the drawing. In addition, a plurality of dotted square frames shown at time t0 indicate processing in which the slaves 21, 22, . . . , 2n measure the voltage or the like of the single battery cell.

As illustrated in FIG. 3, at time tr, the master 30 transmits a Request command to each of the slaves 21, 22, 23, . . . , 2n by broadcast. Each of the slaves 21, 22, . . . , 2n measures a reception strength at the time of receiving the Request command, and stores the measured value of the reception strength in the memory of the wireless device. For example, the slave 21 stores the measured value of the reception strength in the memory of the wireless device 21b (see FIG. 1).

At time t0 after receiving the Request command, each of the slaves 21, 22, . . . , 2n measures the state variable of the single battery cell. For example, the slave 21 measures state variables such as the voltages or temperatures of the plurality of single battery cells 11a (see FIG. 1) of the battery module 11 (see FIG. 1), and stores the measured values in the memory of the wireless device 21b (see FIG. 1).

At time t1, the slave 21 transmits data including the state variable of the single battery cell 11a (see FIG. 1) to the master 30. In a case where the data from the slave 21 is normally received, the master 30 transmits an ACK (positive response) back to the slave 21. In addition, the master 30 measures a reception strength at the time of receiving a radio signal from the slave 21, and stores the measured value in the memory of the wireless device 30b in association with the slave 21 (see FIG. 1).

At time t2, another slave 22 transmits data including a state variable of a single battery cell 12a (see FIG. 1) to the master 30. In the example of FIG. 3, since the master 30 cannot normally receive the data from the slave 22, the master 30 sends an NAK (negative response) back. In the case of receiving this NAK, the slave 22 transmits data including the state variable of the single battery cell 12a (see FIG. 1) to the master 30 again. The master 30 can normally receive the data from the slave 22 this time, and thus sends an ACK back to the slave 22. In addition, the master 30 measures a reception strength at the time of receiving a radio signal from the slave 22, and stores the measured value in the memory of the wireless device 30b in association with the slave 22 (see FIG. 1).

In this manner, the slaves 21, 22, 23, . . . , 2n sequentially respond at shifted timings in response to the Request command from the master 30. Note that in each of the slaves 21, 22, 23, . . . , 2n, a time from the reception of the Request command to the response is preset.

Then, a series of processing illustrated in FIG. 3 is repeated in a predetermined manner with, as one communication cycle, a time from time tr at which the Request command is transmitted to time tn at which the last slave 2n makes a response (for example, 20 [ms] ).

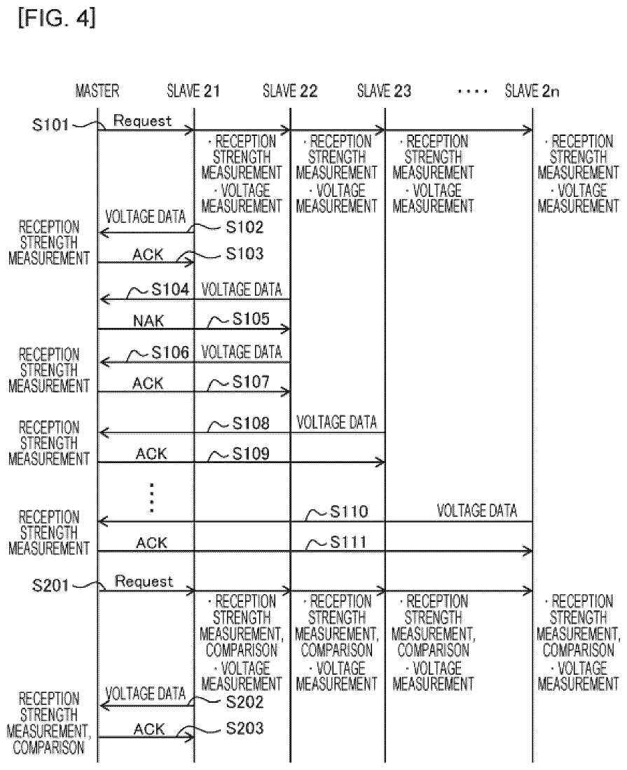

FIG. 4 is a sequence diagram in a case where communication is normally performed in the wireless communication system.

Note that the sequence diagram of FIG. 4 corresponds to the communication timing diagram of FIG. 3, and thus the description thereof will be simplified below. AS illustrated in FIG. 4, in a case where a Request command is received from the master 30 (S101), each of the slaves 21, 22, 23, . . . , 2n measures a reception strength when receiving the Request command, and further measures a voltage or the like of a single battery cell.

In a case where voltage data from the slave 21 is normally received (S102), the master 30 sends an ACK back to the slave 21 (S103), measures a reception strength at the time of receiving the voltage data from the slave 21, and stores the measured value.

In addition, in a case where the voltage data from another slave 22 cannot be normally received (S104), the master 30 sends an NAK back to the slave 22 (S105). In a case where voltage data retransmitted from the slave 22 can be normally received according to the NAK (S106), the master 30 sends an ACK back to the slave 22 (S107), and measures a reception strength at the time of receiving the voltage data from the slave 22. Similarly, the voltage data is sequentially transmitted from the slaves 23, . . . , 2n to the master 30 (S108 to S111).

In a next second communication cycle, the master 30 and the slaves 21, 22, 23, . . . , 2n each compare a current reception strength when they have received a radio signal with a previous reception strength (S201). For example, the slaves 21, 22, . . . , 2n each calculates a difference (absolute value) between the current reception strength at the time of receiving a Request command from the master 30 and the previous reception strength, and stores the value of the difference.

Next, in a case where voltage data from the slave 21 is normally received (S202), the master 30 sends an ACK back to the slave 21, and measures a current reception strength at the time of receiving the voltage data from the slave 21. Then, the master 30 stores a difference (absolute value) between a current reception strength when the master 30 has received a radio signal from the slave 21 and a previous reception strength in association with the slave 21. Similarly, the master 30 calculates a difference (absolute value) between a current reception strength at the time of receiving radio signals from the other slaves 22, 23, . . . , 2n and a previous reception strength, and stores the value of the difference.

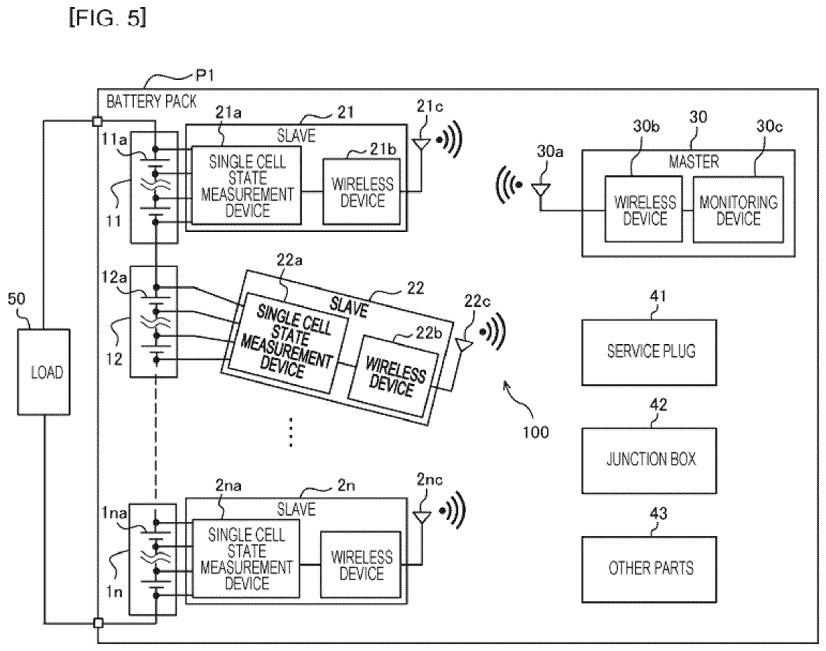

FIG. 5 is a configuration diagram including the wireless communication system 100, and illustrates a state where a position of the slave 22 changes inside the battery pack P1.

For example, in a case where a moving body (not illustrated) on which the battery pack P1 is mounted collides with an object, a strong impact force acts on the battery pack P1. As a result, there is a possibility that parts such as the master 30 and the slaves 21, 22, . . . , 2n move inside the battery pack P1, and a predetermined defect occurs. In addition, even in a case where there is an assembly failure in the battery pack P1 or severe vibration occurs due to an earthquake, there is a possibility that parts such as the master 30 and the slaves 21, 22, . . . , 2n move inside the battery pack P1.

When the arrangement state of the slave 22 changes as illustrated in FIG. 5, there is a possibility that measurement of the state variable of the single battery cell 12a and wireless communication are hindered. In addition, when the arrangement state of the slave 22 changes, a situation when the radio wave of the radio signal is reflected or diffracted inside the battery pack P1 also changes. As a result, a reception strength when wireless communication is performed between the master 30 and the slave 22 becomes higher or lower than that before the position of the slave 22 is changed.

On the other hand, between the slaves 21, 23, . . . , 2n the positions of which have not changed and the master 30, the reception strength of the radio signal hardly changes from that in a normal state. Therefore, in the first embodiment, the master 30 detects the movement of the part (the master 30 itself, the slaves 21, 22, . . . , 2n, and peripheral parts) in the battery pack P1, on the basis of the change in the reception strength when wireless communication is performed between the master 30 and the slaves 21, 22, . . . , 2n.

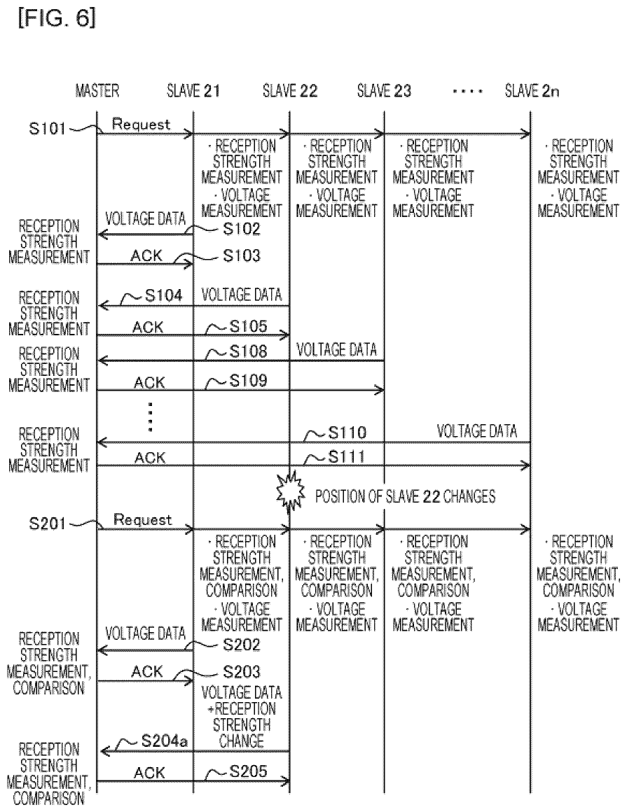

FIG. 6 is a sequence diagram in a case where the position of the slave 22 changes in the wireless communication system.

Note that the processing in steps S101 to S111 (first communication cycle) in FIG. 6 is similar to that in FIG. 4 in a normal state, and thus description thereof is omitted. The example of FIG. 6 illustrates a case where the position of the slave 22 is changed by a predetermined impact between the first communication cycle and the second communication cycle.

For example, for the slave 21 the position of which has not changed, the processing in steps S201 to S203 is performed as in the normal state (see FIG. 4). On the other hand, for the slave 22 the position of which has changed, the difference (absolute value) between the previous reception strength at the time of receiving the radio signal from the master 30 and the current reception strength is greater than or equal to a predetermined value. The “predetermined value” is a threshold serving as a criterion for determining whether or not the slave 22 reports the reception strength to the master 30, and is set in advance.

In the example of FIG. 6, in step S204a, the slave 22 transmits voltage data to the master 30 and reports a change in the reception strength. In a case where these pieces of data are normally received, the master 30 sends an ACK back to the slave 22 in step S205.

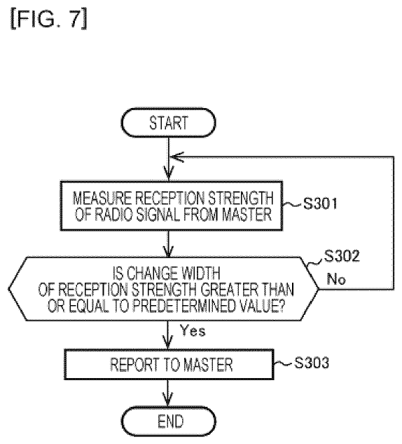

FIG. 7 is a flowchart related to processing of a slave (see also FIG. 5 as appropriate).

In the following example, processing of the slave 22 of n slaves 21, 22, . . . , 2n will be described, but the same applies to the other slaves 21, 23, . . . , 2n. In addition, in FIG. 7, processing other than processing related to detection of a change in reception strength is omitted.

In step S301, the slave 22 measures a reception strength at the time of receiving a radio signal (for example, a Request command) from the master 30.

In step S302, the slave 22 determines whether or not a variation in the reception strength is greater than or equal to a predetermined value. That is, the slave 22 determines whether or not the difference (absolute value) between the previous reception strength at the time of receiving the signal from the master 30 and the current reception strength is greater than or equal to a predetermined value.

In step S302, in a case where the variation in the reception strength is less than the predetermined value (S302: No), the processing of the slave 22 returns to step S301. In addition, in step S302, in a case where the variation in the reception strength is greater than or equal to the predetermined value (S302: Yes), the processing of the slave 22 proceeds to step S103. For example, in a case where a predetermined impact force acts on the battery pack P1 and the position of the slave 22 is changed from an original position (see FIG. 5), the reception strength when the slave 22 receives a signal from the master 30 greatly changes. That is, the reception strength of the radio signal in the slave 22 is often higher or lower than that in the normal state.

In step S303, the slave 22 reports, to the master 30, a fact that the reception strength has changed. For example, when transmitting the voltage data to the master 30, the slave 22 also reports the change in the reception strength (corresponding to S204a in FIG. 6). As described above, in a case where the variation in the reception strength at the time of receiving the radio signal from the master 30 (battery management device) is greater than or equal to the predetermined value (S302: Yes), each of the plurality of slaves 21, 22, . . . , 2n (a plurality of battery data transmission devices) reports the change in the reception strength to the master 30 (S303).

After performing the processing of step S303, the slave 22 ends the series of processing (END). Note that the series of processing illustrated in FIG. 7 is individually performed each time each of the slaves 21, 22, . . . , 2n receives the radio signal from the master 30.

Note that each time the processing of step S302 (determination of the variation in the reception strength) is performed, the data of the previous reception strength and the data of the current reception strength may be overwritten. In addition, an absolute value of a difference between an average value of reception strengths of a plurality of times up to the previous time and the current reception strength may be used as the variation in the reception strength in step S302. Further, in a case where the variation in the reception strength is greater than or equal to the predetermined value (S302: Yes), when the slave 22 calculates the variation in the reception strength again after the next time, the current reception strength in which the variation is large may not be used to calculate a reference average value (an average value of reception strengths of a plurality of times). Accordingly, the reference average value of reception strengths is easily maintained in a normal range.

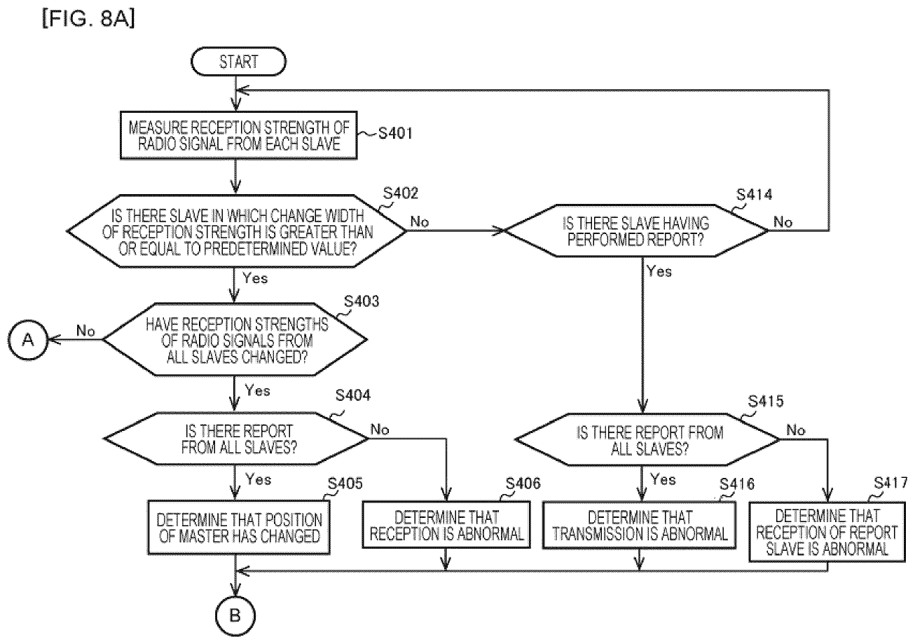

FIGS. 8A and 8B are flowcharts related to processing of a master (see also FIG. 1 as appropriate).

In step S401, the master 30 measures reception strengths at the time of receiving radio signals such as voltage data from the slaves 21, 22, . . . , 2n.

In step S402, the master 30 determines whether or not there is a slave, which has a variation in a reception strength greater than or equal to the predetermined value, among the slaves 21, 22, . . . , 2n. For example, it may be determined whether or not an absolute value (that is, a variation) of a difference between the previous reception strength when the master 30 has received the signal and the current reception strength is greater than or equal to the predetermined value. In addition, as the variation in the reception strength, an absolute value of a difference between an average value of reception strengths of a plurality of times up to the previous time and the current reception strength may be used.

In step S402, in a case where there is a slave, which has a variation in a reception strength greater than or equal to the predetermined value, among the slaves 21, 22, . . . , 2n (S402: Yes), the processing of the master 30 proceeds to step S403.

In step S403, the master 30 determines whether or not the reception strengths of the radio signals from all the slaves 21, 22, . . . , 2n have changed. That is, the master 30 determines whether or not transmission sources of the radio signals when the variation in the reception strength when the master 30 receives the signal is greater than or equal to the predetermined value are all the slaves 21, 22, . . . , 2n. In step S403, in a case where the reception strengths of the radio signals from all the slaves 21, 22, . . . , 2n have changed (S403: Yes), the processing of the master 30 proceeds to step S404.

In step S404, the master 30 determines whether or not there is the report of the change in the reception strength (corresponding to S303 in FIG. 7) from each of all the slaves 21, 22, . . . , 2n. In a case where there is the report of the change in the reception strength from each of all the slaves 21, 22, . . . , 2n (S404: Yes), the processing of the master 30 proceeds to step S405.

In step S405, the master 30 determines that the position of the master 30 itself has changed. This is because, since the slaves 21, 22, . . . , 2n are usually firmly fixed to the battery pack P1 with screws or the like, even in a case where a strong impact force acts, there is almost no change in all the positions of the slaves.

In addition, in step S404, in a case where there is a slave that has not reported the change in the reception strength (S404: No), the processing of the master 30 proceeds to step S406.

In step S406, the master 30 determines that the master 30 itself has a reception abnormality. This is because, in this case, the change in the reception strength in the master 30 does not match the report of the change in the reception strength from a predetermined slave.

In addition, in step S403, in a case where a situation in which the reception strengths of the radio signals from all the slaves 21, 22, . . . , 2n have changed does not occur (S403: No), the processing of the master 30 proceeds to step S407 in FIG. 8B. That is, in a case where the transmission source when the variation in the reception strength when the master 30 receives the radio signal is greater than or equal to the predetermined value is a part of the slaves 21, 22, . . . , 2n, the processing of the master 30 proceeds to step S407.

In step S407 of FIG. 8B, the master 30 determines whether or not the reception strengths of the radio signals from a plurality of slaves have changed. That is, the master 30 determines whether or not the transmission sources when the variation in the reception strength when the master 30 itself receives the radio signal is greater than or equal to the predetermined value are the plurality of slaves. In step S407, in a case where the reception strengths of the radio signals from the plurality of slaves have changed (S407: Yes), the processing of the master 30 proceeds to step S408.

In step S408, the master 30 determines whether or not a target slave matches the slave that has reported the change in the reception strength. Here, the “target slave” is a transmission source slave when a variation in a reception strength is greater than or equal to the predetermined value when the master 30 receives a radio signal. In step S408, in a case where the target slave matches the slave that reported the change in reception strength (S408: Yes), the processing of the master 30 proceeds to step S409.

In step S409, the master 30 determines that the positions of the plurality of slaves have changed. This is because, in this case, the change in the reception strength when the master 30 receives the radio signal matches the report of the change in the reception strength from the plurality of slaves.

In addition, in step S408, in a case where the target slave does not match the slave that has reported the change in the reception strength (S408: No), the processing of the master 30 proceeds to step S410.

In step S410, the master 30 determines that the positions of the peripheral parts have changed. Here, the “peripheral parts” are parts housed in the battery pack P1 except for the master 30 and the slaves 21, 22, . . . , 2n. In the example of FIG. 1, the service plug 41, the junction box 42, and the other parts 43 correspond to the “peripheral parts”. When the positions of the peripheral parts change, a situation when the radio wave is reflected or diffracted inside the battery pack P1 is different from the normal state. As a result, the reception strength often changes when wireless communication is performed between the master 30 and a predetermined slave.

In addition, in step S407, in a case where a situation in which the reception strengths of the radio signals from the plurality of slaves have changed does not occur (S407: No), the processing of the master 30 proceeds to step S411. That is, in a case where the number of transmission source slaves when the variation in the reception strength in the master 30 is greater than or equal to the predetermined value is one, the processing of the master 30 proceeds to step S411.

In step S411, the master 30 determines whether or not there is the report of the change in the reception strength from the target slave. That is, the master 30 determines whether or not the transmission source slave (target slave) when the variation in the reception strength when the master 30 has received the radio signal is greater than or equal to the predetermined value matches the slave that has reported the change in the reception strength. In step S411, in a case where there is the report of the change in the reception strength from the target slave (S411: Yes), the processing of the master 30 proceeds to step S412.

In step S412, the master 30 determines that the position of the target slave has changed. This is because, in this case, the change in the reception strength of the radio signal in the master 30 matches the report of the change in the reception strength from the target slave. In addition, in step S411, in a case where there is not the report of the change in the reception strength from the target slave (S411: No), the processing of the master 30 proceeds to step S413.

In step S413, the master 30 determines that the transmission abnormality of the target slave occurs. This is because, in this case, when the master 30 receives the radio signal from the target slave, there is no report of the change in the reception strength from the target slave even though the reception strength has changed.

In addition, in step S402 of FIG. 8A, in a case where there is no slave, which has a variation in a reception strength greater than or equal to the predetermined value, among the slaves 21, 22, . . . , 2n (S402: No), the processing of the master 30 proceeds to step S414.

In step S414, the master 30 determines whether or not there is a slave that has reported the change in the reception strength. In a case where there is a slave that has reported the change in the reception strength (S414: Yes), the processing of the master 30 proceeds to step S415.

In step S415, the master 30 determines whether or not there is the report of the change in the reception strength from all the slaves 21, 22, . . . , 2n. In a case where there is the report of the change in the reception strength from all the slaves 21, 22, . . . , 2n (S415: Yes), the processing of the master 30 proceeds to step S416.

In step S416, the master 30 determines that the transmission abnormality of the master 30 itself occurs. This is because, in this case, although the reception strength of the radio signal has not changed in the master 30 (S402: No), the reception strength of the radio signal has changed in all the slaves 21, 22, . . . , 2n (S415: Yes), and there is a high possibility that the radio signal has not been normally transmitted from the master 30.

In addition, in step S415, in a case where there is a slave that has not reported the change in the reception strength (S415: No), the processing of the master 30 proceeds to step S417.

In step S417, the master 30 determines that the reception abnormality of a reporting slave occurs. That is, the master 30 determines that the reception abnormality occurs in one or more slaves which have reported the change in the reception strength. If the transmission abnormality were to occur on the master 30 side, there is a high possibility that there is the report of the change in the reception strength from all the slaves 21, 22, . . . , 2n, but this does not occur.

In addition, in step S414, in a case where there is no slave that has reported the change in the reception strength (S414: No), the processing of the master 30 returns to step S401. In this case, the reception strength of the radio signal does not change in any of the master 30 and the slaves 21, 22, . . . , 2n, and wireless communication is performed as usual. Then, the master 30 receives the radio signal again from each of the slaves 21, 22, . . . , 2n in the next communication cycle, and measures the reception strength.

As described above, the master 30 (battery management device) detects the change in the arrangement state of the “parts” on the basis of the presence or absence of the change in the reception strength at the time of receiving the radio signal from each of the plurality of slaves 21, 22, . . . , 2n (battery data transmission devices) and the report of the change in the reception strength. The “parts” described above include, in addition to the master 30 and the slaves 21, 22, . . . , 2n, peripheral parts such as the service plug 41 (see FIG. 1), the junction box 42 (see FIG. 1), and the other parts 43 (see FIG. 1).

After any processing of steps S409, S410, S412, and S413 in FIG. 8B in addition to steps S405, S406, S416, and S417 in FIG. 8A is performed, the processing of the master 30 proceeds to step S418.

In step S418, the master 30 transmits a determination result to the host CPU (not illustrated). In this case, the host CPU notifies a user that an abnormality has occurred in the part of the battery pack P1. For example, in a case where the battery pack P1 is mounted on a moving body (not illustrated), the host CPU may cause a display device (not illustrated) of the moving body to display information indicating that an abnormality has occurred in the part of the battery pack P1. In addition, the information indicating that an abnormality has occurred in the part of the battery pack P1 may be displayed on a mobile terminal (not illustrated) of the user, or may be notified to a service center (not illustrated) that performs repair or the like.

After performing the processing of step S418, the master 30 ends the series of o processing (END). Note that the series of processing illustrated in FIGS. 8A and 8B is performed every predetermined communication cycle.

### Effects

According to the first embodiment, the change in the arrangement state of the parts in the battery pack P1 can be appropriately detected on the basis of the change in the reception strength when wireless communication is performed between the master 30 and the slaves 21, 22, . . . , 2n. Accordingly, it is possible to prevent the user from continuing to use the battery pack P1 without being aware that the master 30, the slaves 21, 22, . . . , 2n, and the peripheral parts have moved inside the battery pack P1. Therefore, it is possible to prevent a part failure, a power short circuit, or the like in the battery pack P1 in advance.

In addition, according to the first embodiment, since it is not particularly necessary to connect an external device (not illustrated) to the battery pack P1 as in PTL 1 described above, it is possible to detect the movement of parts even during normal use of the battery pack P1. In addition to the components such as the master 30 and the slaves 21, 22, . . . , 2n, the movement of peripheral parts such as the service plug 41, the junction box 42, and the other parts 43 can also be appropriately detected.

### Modification of First Embodiment

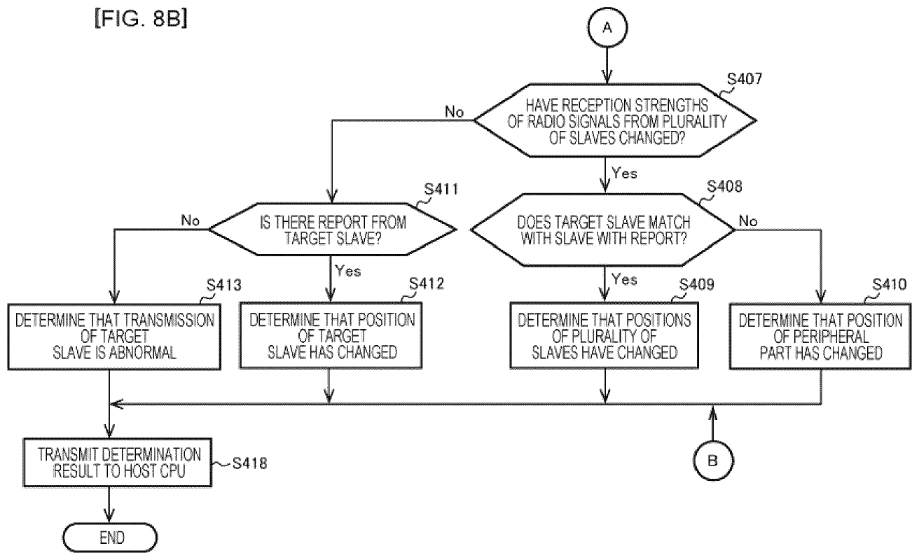

FIG. 9 is an explanatory diagram illustrating a relationship between the master 30 and the plurality of slaves 21, 22, 23, . . . , 2n in a wireless communication system 100A according to a modification of the first embodiment.

For example, when the slave 23 performs wireless communication with the master 30, another predetermined slave or a peripheral part interferes, and the wireless communication may not be directly performed. In such a case, a radio signal may be transmitted from the slave 23 to the master 30 via another slave 22. In addition, a radio signal may be transmitted from the master 30 to the slave 23 via another slave 22. That is, the plurality of slaves 21, 22, 23, . . . , 2n (battery data transmission devices) may include one slave (the slave 22 in the example of FIG. 9) that is interposed between a predetermined slave 23 and the master 30 (battery management device) and relays wireless communication.

Accordingly, even in a case where wireless communication cannot be directly performed between the master 30 and the slave 23, wireless communication can be performed via another slave 22. Note that the slave 22 interposed between the master 30 and the slave 23 may be set in advance, or may be appropriately set for each communication cycle.

In addition, the slave 22 illustrated in FIG. 9 may play at least a part of the role of the master with respect to the other slave 23. For example, in a case where the slave 22 receives the report of the change in the reception strength from the slave 23, the slave 22 may report the change in the reception strength to the master 30 in association with the slave 23.

### Second Embodiment

A second embodiment is different from the second embodiment in that the slaves 21, 22, . . . , 2n do not particularly report the change in the reception strength (or even if there is a report, the report is not used by the master 30), and the change in the arrangement state of the parts is detected on the basis of the change in the reception strength when the master 30 receives the radio signal. Note that the configuration of the battery pack P1 (see FIG. 1) and the wireless communication system 100 (see FIG. 1) is similar to that of the first embodiment. Therefore, portions different from those of the first embodiment will be described, and description of redundant portions will be omitted.

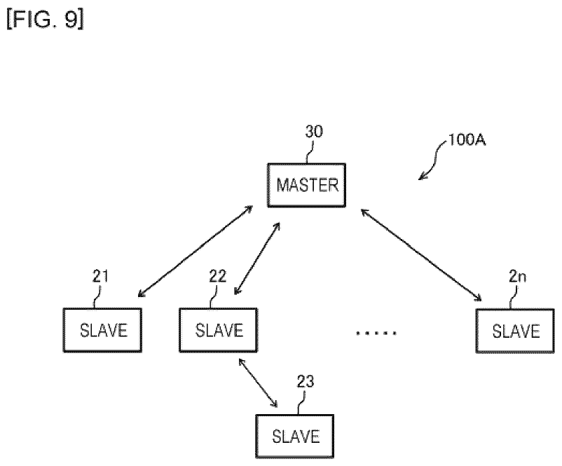

FIG. 10 is a flowchart related to processing of a master of a wireless communication system according to the second embodiment (see also FIG. 1 as appropriate).

Note that the processing in steps S501 to S503 and S505 in FIG. 10 is similar to the processing in steps S401 to S403 (see FIG. 8A) and S407 (see FIG. 8B) in the first embodiment in this order, but will be briefly described below. That is, the master 30 measures the reception strength at the time of receiving the radio signal from the slaves 21, 22, . . . , 2n (S501), and in a case where there is a slave in which a variation in a reception strength is greater than or equal to the predetermined value (S502: Yes), when the reception strengths from all the slaves have changed (S503: Yes), the processing proceeds to the processing of step S504.

In step S504, the master 30 determines that the position of the master 30 itself has changed. This is because, since the slaves 21, 22, . . . , 2n are usually firmly fixed to the battery pack P1 with screws or the like, even in a case where a strong impact force acts, there is almost no change in all the positions of the slaves.

In addition, in step S503, in a case where there is a slave in which the reception strength of the radio signal has not changed (S503: No), when the reception strengths of the radio signals from a plurality of slaves have changed (S505: Yes), the processing of the master 30 proceeds to step S506.

In step S506, the master 30 determines that the positions of the plurality of slaves or a peripheral part have changed. This is because when the positions of the plurality of slaves and the peripheral part change, a situation when the radio wave is reflected or diffracted inside the battery pack P1 is different from the normal state.

In addition, in step S505, in a case where a situation in which the reception strengths of the radio signals from the plurality of slaves have changed does not occur (S505: No), the processing of the master 30 proceeds to step S507. That is, in a case where the number of transmission source slaves when the reception strength of the radio signal in the master 30 has changed is one, the processing of the master 30 proceeds to step S507.

In step S507, the master 30 determines that the position of one slave has changed. That is, the master 30 determines that the position of one slave that is the transmission source when the reception strength of the radio signal changes has changed. As described above, the master 30 (battery management device) detects the change in the arrangement state of the parts on the basis of the presence or absence of the change in the reception strength at the time of receiving the radio signal from each of the plurality of slaves 21, 22, . . . , 2n (battery data transmission devices).

In addition, in step S502, in a case where there is no slave in which the variation in the reception strength is greater than or equal to the predetermined value (S502: No), the processing of the master 30 returns to step S501. Then, the master 30 receives the radio signal again from each of the slaves 21, 22, . . . , 2n in the next communication cycle, and measures the reception strength.

After performing any of the processing of steps S504, S506, and S507, the master 30 transmits a determination result to the host CPU (not illustrated) in step S508, and ends the series of processing (END). Note that the series of processing illustrated in FIG. 10 is performed every predetermined communication cycle.

### Effects

According to the second embodiment, since it is not particularly necessary to report the change in the reception strength from the slaves 21, 22, . . . , 2n to the master 30, the processing of the slaves 21, 22, . . . , 2n in the wireless communication system 100 can be simplified.

### Third Embodiment

A third embodiment is different from the first embodiment in that the reception strength when the master 30 receives the radio signal is not particularly measured (or even if the reception strength is measured, the reception strength is not particularly used for determining the position change of the part), and the change in the arrangement state of the part is detected on the basis of the report of the change in the reception strength from the slaves 21, 22, . . . , 2n. Note that the battery pack P1 (see FIG. 1) and the wireless communication system 100 (see FIG. 1) are similar to those of the first embodiment. Therefore, portions different from those of the first embodiment will be described, and description of redundant portions will be omitted.

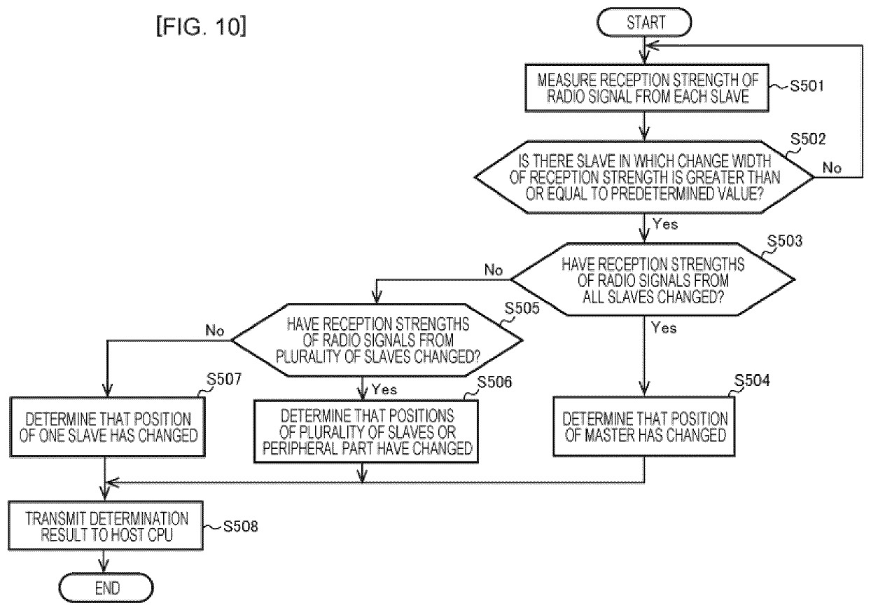

FIG. 11 is a flowchart related to processing of a master of a wireless communication system according to the third embodiment (see also FIG. 1 as appropriate).

Note that although not illustrated in FIG. 11, the processing performed by each of the slaves 21, 22, . . . , 2n (see FIG. 7) is similar to that of the first embodiment. That is, in a case where the variation in the reception strength at the time of receiving the radio signal from the master 30 (battery management device) is greater than or equal to the predetermined value, each of the plurality of slaves 21, 22, . . . , 2n (battery data transmission devices) reports the change in the reception strength to the master 30.

In step S601 of FIG. 11, the master 30 determines whether or not there is the report of the change in the reception strength from at least one of the slaves 21, 22, . . . , 2n. In a case where there is the report of the change in the reception strength from at least one of the slaves 21, 22, . . . , 2n (S601: Yes), the processing of the master 30 proceeds to step S602.

In step S602, the master 30 determines whether or not there is the report of the change in the reception strength from all the slaves 21, 22, . . . , 2n. In a case where there is the report of the change in the reception strength from all the slaves 21, 22, . . . , 2n (S602: Yes), the processing of the master 30 proceeds to step S603.

In step S603, the master 30 determines that the position of the master 30 itself has changed. This is because, since the slaves 21, 22, . . . , 2n are usually firmly fixed to the battery pack P1 with screws or the like, even in a case where a strong impact force acts, there is almost no change in all the positions of the slaves.

In addition, in step S602, in a case where there is a slave that has not reported the change in the reception strength (S602: No), the processing of the master 30 proceeds to step S604.

In step S604, the master 30 determines whether or not there is the report of the change in the reception strength from the plurality of slaves. In a case where there is the report of the change in the reception strength from the plurality of slaves (S604: Yes), the processing of the master 30 proceeds to step S605.

In step S605, the master 30 determines that the positions of a plurality of slaves or a peripheral part have changed. This is because when the positions of the plurality of slaves and the peripheral part change, a situation when the radio wave is reflected or diffracted inside the battery pack P1 is different from the normal state.

In addition, in step S604, in a case where there is not the report of the change in the reception strength from the plurality of slaves (S604: No), the processing of the master 30 proceeds to step S605. That is, in a case where the number of slaves which have reported the change in the reception strength is one, the processing of the master 30 proceeds to step S606.

In step S606, the master 30 determines that the position of one slave has changed. That is, the master 30 determines that the position of one slave that has reported the change in the reception strength has changed. As described above, the master 30 (battery management device) detects the change in the arrangement state of the parts on the basis of the report of the change in the reception strength from the slaves 21, 22, . . . , 2n (battery data transmission devices).

In addition, in step S601, in a case where there is no slave that has reported the change in the reception strength (S601: No), the master 30 repeats the processing of step S601. Then, the master 30 receives the radio signal such as voltage data from the respective slaves 21, 22, . . . , 2n in the next communication cycle.

After performing any of the processing of steps S603, S605, and S606, the master 30 transmits the determination result to the host CPU (not illustrated) in step S607, and ends the series of processing (END). Note that the series of processing illustrated in FIG. 11 is performed every predetermined communication cycle.

### Effects

According to the third embodiment, since it is not particularly necessary to measure the reception strength when the master 30 receives the radio signal from the slaves 21, 22, . . . , 2n, the processing of the master 30 in the wireless communication system 100 can be simplified.

### Fourth Embodiment

A fourth embodiment is different from the first embodiment in that wireless communication is performed in a channel including a frequency of a null point where a reception strength of a radio signal is relatively low. Note that the configuration of the battery pack P1 (see FIG. 1) and the wireless communication system 100 (see FIG. 1) is similar to that of the first embodiment. Therefore, portions different from those of the first embodiment will be described, and description of redundant portions will be omitted.

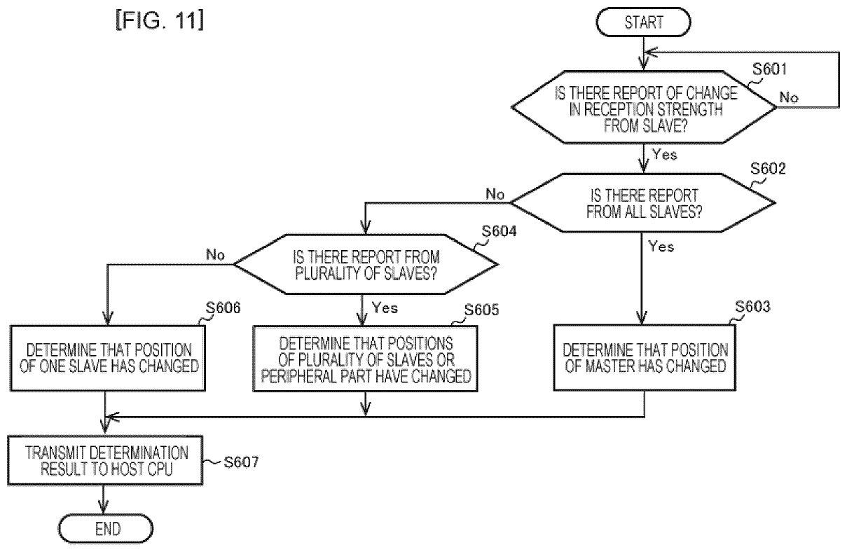

FIG. 12 is an explanatory diagram illustrating an example of a frequency characteristic of a reception strength between a master and a slave in a wireless communication System according to the fourth embodiment (see also FIG. 1 as appropriate).

Note that in FIG. 12, a horizontal axis represents the frequency, and a vertical axis represents the reception strength. In addition, a solid line indicated by “slave 21” in FIG. 12 indicates the frequency characteristic of the reception strength when the slave 21 receives the radio signal from the master 30. The same applies to the frequency characteristics of other “slave 22” and “slave 23”.

Since the slaves 21, 22, and 23 are housed in the metal battery pack P1, reflection and diffraction of radio waves occur inside the battery pack P1. In addition, when the slaves 21, 22, and 23 receive a radio signal, a point (null point) at which the reception strength decreases extremely (for example, by 20 [dB] or more) is often generated depending on the frequency of the radio signal. In the example of FIG. 12, the null point of the reception strength when the slave 21 receives the radio signal from the master 30 is a frequency f1. Similarly, the null point of the slave 22 is a frequency f2, and the null point of the slave 23 is a frequency f3.

In the example of FIG. 12, the frequencies f1, f2, and f3 of the null points are different in magnitude. These frequencies f1, f2, and f3 are determined by, for example, the arrangement of the master 30, the slaves 21, 22, and 23, and the peripheral parts in the battery pack P1 in addition to the shape of the battery pac P1. For example, at the frequency f1 of the null point, the reception strength when the slave 21 receives the radio signal from the master 30 becomes extremely low, but it is also possible to perform wireless communication at this null point.

Note that, although not illustrated in FIG. 12, even when the master 30 receives a radio signal from each of the slaves 21, 22, and 23, null points often occur at which the reception strength is extremely low, but it is also possible to perform wireless communication at these null points. As described above, a frequency characteristic in the wireless communication between the master 30 (battery management device) and the slaves 21, 22, and 23 (predetermined battery data transmission devices) includes a null point where the reception strength of the radio signal is lower than other frequencies by a predetermined value (for example, 20 [dB] ) or more.

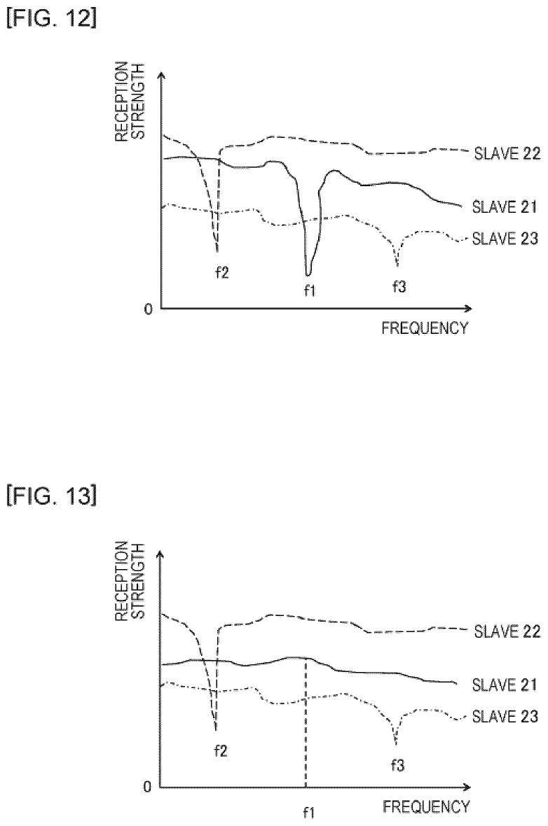

FIG. 13 is an explanatory diagram illustrating an example of the frequency characteristic of the reception strength between the master and the slave, and illustrates a case where a null point disappears as the position of the slave 21 changes.

For example, although the frequency f1 of the null point exists at the original position (position before movement) of the slave 21 (see FIG. 12), the null point often disappears even in a case where the position of the slave 21 slightly changes (see FIG. 13). Comparing FIG. 12 with FIG. 13, the reception strength of the slave 21 at the frequency f1 considerably changes depending on the presence or absence of the null point. Note that, even in a case where the null point remains without disappearing, a sensitivity to the change in the position of the slave 21 is considerably high since the frequency characteristic is steep near the null point. In this regard, in the fourth embodiment, a channel that is a use frequency band of a radio frequency is set as follows.

That is, when wireless communication is performed between the master 30 (battery management device) and the plurality of slaves 21, 22, and 23 (battery data transmission devices), a channel that is a use frequency band of the wireless communication is set to include a null point. As a specific example, when wireless communication is performed between the master 30 and the slaves 21, 22, and 23, the channel may be switched for each communication cycle in the order of the frequencies f1, f2, and f3 such that a first channel including the frequency f1 is used in a first communication cycle, a second channel including the frequency f2 is used in a second communication cycle, and a third channel including the frequency f3 is used in a third communication cycle.

In this case, when calculating the variation in the reception strength of the radio signal from the master 30, the slave 21 calculates a difference between the reception strength in the latest communication cycle in which the wireless communication is performed in the channel including the frequency f1 and the reception strength when the communication is performed in the channel before the communication cycle. The master 30 similarly calculates the variation in the reception strength at the time of receiving the radio signal from the slave 21. The same applies to wireless communication between the master 30 and other slaves 22 and 23.

As described above, in a case where there are a plurality of the predetermined slaves 21, 22, and 23 (battery data transmission devices) having a frequency characteristic including a null point, in the wireless communication between the master 30 (battery management device) and the plurality of slaves 21, 22, and 23 (battery data transmission devices), the channel that is the use frequency band of the wireless communication is periodically switched so as to include the null point. Accordingly, a change in position can be detected with high sensitivity for the slaves 21, 22, and 23 having different frequencies f1, f2, and f3 of the null points. Note that while FIGS. 12 and 13 illustrate three slaves 21, 22, and 23, the same applies to other slaves.

### Effects

According to the fourth embodiment, when the master 30 and the slaves 21, 22, . . . , 2n perform wireless communication, a channel that is a use frequency band is set to include a null point. Accordingly, changes in the positions of the master 30, the slaves 21, 22, . . . , 2n, and peripheral parts can be detected with high sensitivity.

### Modification

Although the wireless communication system 100 and the wireless communication method according to the present disclosure have been described in each embodiment, the present disclosure is not limited to these descriptions, and various modifications can be made.

For example, in each embodiment, a case where the change in the reception strength is reported from the slave 21 to the master 30 at a transmission timing of voltage data has been described, but the present invention is not limited thereto. That is, the transmission of the voltage data and the report of the change in the reception strength may be performed at different timings.

In addition, in the first embodiment and the third embodiment, the processing in which in a case where the variation in the reception strength of the radio signal in the slave 21 is greater than or equal to the predetermined value (S302: Yes in FIG. 7), the slave 21 reports the change in the reception strength to the master 30 (S303) has been described. However, the present invention is not limited to this. That is, every time the slave 21 receives a radio signal from the master 30, the slave 21 may transmit the measured value of its own reception strength to the master 30. Then, the master 30 may determine whether or not the variation in the reception strength in the slave 21 is greater than or equal to the predetermined value (the same applies to other slaves 22, . . . , 2n).

In addition, in the fourth embodiment, a case where a null point is included in the frequency identification of each of three slaves 21, 22, and 23 has been described, but the present invention is not limited thereto. For example, some of the slaves 21, 22, . . . , 2n may each have a null point in the frequency characteristic at an original installation position, and the others may not each have a null point in the frequency characteristic at the original installation position. Even in this case, the change in the position of the slave or the like can be detected with high sensitivity by the master 30 switching the channel including the null point for each communication cycle.

In addition, in each embodiment, a case where the wireless device 21b (wireless communication unit) and the antenna 21c (wireless communication unit) are separately provided in the slave 21 (see FIG. 1) has been described, but these may be integrated. Note that the same applies to the other slaves 22, . . . , 2n.

In addition, in each embodiment, a case where the wireless device 30b (wireless communication unit) and the antenna 30a (wireless communication unit) are separately provided in the master 30 (see FIG. 1) has been described, but these may be integrated.

In addition, the processing (wireless communication method) of the wireless communication system 100 may be executed as a predetermined program of a computer. The above-described program can be provided via a communication line, and can also be distributed by being written in a recording medium such as a CD-ROM.

In addition, the present disclosure is not limited to each embodiment, and various modifications are included. For example, each embodiment has been described in detail for easy understanding of the present disclosure and is not necessarily limited to those having all the described configurations. In addition, a part of the configuration of a certain embodiment can be replaced with the configuration of another embodiment, and the configuration of another embodiment can be added to the configuration of a certain embodiment. In addition, it is possible to add, delete, and replace other configurations for a part of the configuration of each embodiment.

Each of the above-described configurations, functions, processing units, processing means, and the like may be realized by hardware by designing a part or all of them with, for example, an integrated circuit. In addition, each of the above-described configurations, functions, and the like may be realized by software by a processor interpreting and executing a program for realizing each function. Information such as a program, a table, and a file for realizing each function can be stored in a recording device such as a memory, a hard disk, or a solid state drive (SSD), or a recording medium such as an IC card, an SD card, or a DVD.

In addition, control lines and information lines are described in consideration of necessity for the description, and all control lines and information lines in the product are not necessarily described. In practice, it may also be considered that almost all configurations are connected to each other.

### Reference Signs List

11,12, . . . , 1n battery module
11a, 12a, . . . , 1na single battery cell
21, 22, . . . , 2n slave (component, part, battery data transmission device)
21a, 22a, . . . , 2na single cell state measurement device
21b, 22b, . . . , 2nb wireless device (wireless communication unit)
21c, 22c, . . . , 2nc antenna (wireless communication unit)
30 master (component, part, battery management device)
30a antenna (wireless communication unit)
30b wireless device (wireless communication unit)
30c monitoring device
41 service plug (part, peripheral part)
42 junction box (part, peripheral part)
43 other parts (parts, peripheral parts)
50 load
100, 100A wireless communication system
P1 battery pack

1. A wireless communication system which, detects, on a basis of a change in reception strength when wireless communication is performed between a plurality of components each including a wireless communication unit, a change in an arrangement state of parts, including the plurality of components, arranged inside a battery pack.

2. The wireless communication system according to claim 1, wherein
the components each including the wireless communication unit include a plurality of battery data transmission devices which are connected one-to-one to a plurality of battery modules inside the battery pack, and a battery management device which performs wireless communication with the plurality of battery data transmission devices.

3. The wireless communication system according to claim 1, wherein
the parts include a peripheral part which does not perform wireless communication.

4. The wireless communication system according to claim 2, wherein
in a case where a variation in reception strength at a time of receiving a radio signal from the battery management device is greater than or equal to a predetermined value, each of the plurality of battery data transmission devices reports a change in the reception strength to the battery management device, and
the battery management device detects the change in the arrangement state of the parts on a basis of presence or absence of a change in reception strength at a time of receiving a radio signal from each of the plurality of battery data transmission devices and the report.

5. The wireless communication system according to claim 2, wherein
the battery management device detects the change in the arrangement state of the parts on a basis of presence or absence of a change in reception strength at a time of receiving a radio signal from each of the plurality of battery data transmission devices.

6. The wireless communication system according to claim 2, wherein
in a case where a variation in reception strength at a time of receiving a radio signal from the battery management device is greater than or equal to a predetermined value, each of the plurality of battery data transmission devices reports a change in the reception strength to the battery management device, and
the battery management device detects the change in an arrangement state of the parts on a basis of the report.

7. The wireless communication system according to claim 2, wherein
the plurality of battery data transmission devices includes a device which is interposed between a predetermined battery data transmission device of the battery data transmission devices and the battery management device and relays wireless communication.

8. The wireless communication system according to claim 2, wherein
a frequency characteristic in wireless communication between the battery management device and a predetermined battery data transmission device of the battery data transmission devices includes a null point at which a reception strength of a radio signal is lower than other frequencies by a predetermined value or more, and
when wireless communication is performed between the battery management device and the plurality of battery data transmission devices, a channel that is a use frequency band of the wireless communication is set to include the null point.

9. The wireless communication system according to claim 8, wherein
there are a plurality of predetermined battery data transmission devices of the battery data transmission devices having the frequency characteristic including the null point, and
in wireless communication between the battery management device and the plurality of the battery data transmission devices, the channel is periodically switched to include the null point.

10. A wireless communication method comprising: detecting, on a basis of a change in reception strength when wireless communication is performed between a plurality of components each including a wireless communication unit, a change in an arrangement state of parts, including the plurality of components, arranged inside a battery pack.
